(19) United States
(12) Patent Application Publication
(10) Pub. No.: US 2024/0188360 A1
(43) Pub. Date: Jun. 6, 2024

(54) FLEXIBLE DISPLAY DEVICE

(71) Applicant: LG Display Co., Ltd., Seoul (KR)

(72) Inventors: JuhnSuk YOO, Seoul (KR); YuHo JUNG, Paju-si (KR); Sungki HONG, Incheon (KR)

(73) Assignee: LG Display Co., Ltd., Seoul (KR)

(21) Appl. No.: 18/527,071

(22) Filed: Dec. 1, 2023

(30) Foreign Application Priority Data
Dec. 6, 2022 (KR) 10-2022-0168981

(51) Int. Cl. H10K 59/131; H10K 59/124

(52) U.S. Cl. CPC H10K 59/131; H10K 59/124; H10K 2102/311

(57) ABSTRACT

A flexible display device includes in on example a substrate having an optical area and a main area in a display area, and a bending area and a non-bending area in a non-display area. The flexible display device further includes a first insulating film disposed on the substrate, a wiring line disposed on the insulating film of the non-bending area, a second insulating film disposed on the wiring line, a connection line disposed on the second insulating film of the non-bending area and having a first contact area, a first planarization layer disposed on the connection line, a link line disposed on the first planarization layer to extend to the bending area and having a second contact area, a second planarization layer disposed on the link line and including an open area, and a third insulating film disposed on the second planarization layer and filled in the open area.

### CROSS-REFERENCE TO RELATED APPLICATIONS

This application claims priority to Korean Patent Application No. 10-2022-0168981 filed on Dec. 6, 2022, in the Korean Intellectual Property Office, the entire disclosure of which is hereby expressly incorporated by reference into the present application.

### BACKGROUND

### Field

The present disclosure relates to a flexible display device, and more particularly to a flexible display device which is capable of reducing a bezel width.

### Discussion of the Related Art

As the world enters an information era, a field of a display device which visually expresses electrical information signals has been rapidly developed and studies are continued to improve performances of various display devices, such as a thin-thickness, a light weight, and low power consumption.

A representative display device can include a liquid crystal display (LCD) device, a field emission display (FED) device, an electro-wetting display (EWD) device, an organic light emitting display (OLED) device, and the like.

An electroluminescent display device which is represented by an organic light emitting display device is a self-emitting display device so that a separate light source is not necessary, which is different from a liquid crystal display apparatus. Therefore, the electroluminescent display device can be manufactured to have a light weight and a small thickness. Further, since the electroluminescent display device is advantageous not only in terms of power consumption due to the low voltage driving, but also in terms of color implementation, a response speed, a viewing angle, a contrast ratio (CR), the electroluminescent display device have excellent properties and can be utilized in various fields.

The electroluminescent display device forms a light emitting diode by disposing an emission layer between two electrodes of an anode electrode and a cathode electrode. When holes in the anode electrode are injected into the emission layer and electrons in the cathode electrode are injected into the emission layer, the injected electrons and holes are recombined to form excitons in the emission layer to emit light.

In the meantime, efforts are continued to be made to reduce a bezel area which is an outer periphery of the display area in order to increase an effective display screen size with the same area of the display device.

However, in the bezel area corresponding to the non-display area, a wiring line and a driving circuit for driving the screen can be disposed, which can be a limitation in reducing the bezel area.

### SUMMARY OF THE DISCLOSURE

Recently, with regard to a flexible electroluminescent display device which maintains a display performance even though it is bent by applying a flexible substrate of a flexible material such as plastic, there is an effort to reduce the bezel area by bending the non-display area of the flexible substrate to reduce the bezel area while ensuring the area for the wiring line and the driving circuit. Hereinafter, for the convenience of description, such a display device is referred to as a bezel bending display device.

In the meantime, in a structure in which a bezel bending display device for reducing a bezel width is applied to apply two line layers and two planarization layers, in order to improve productivity, photo-acryl (PAC) is applied as the planarization layer. In this case, a corrosion defect issue can be generated in a gate in panel (GIP) line unit in the vicinity of a contact hole which is adjacent to the bending area.

Therefore, an object to be achieved by the present disclosure is to provide a flexible light emitting display which addresses or minimizes a corrosion defect issue of the GIP line unit while improving the productivity.

Objects of the present disclosure are not limited to the above-mentioned objects, and other objects, which are not mentioned above, can be clearly understood by those skilled in the art from the following descriptions.

In order to achieve the above-described objects, according to an aspect of the present disclosure, a flexible display device can include a substrate which includes a display area divided into an optical area and a normal area (main area) and a non-display area divided into a bending area and a non-bending area; an insulating film disposed on the substrate; a wiring line disposed on the insulating film of the non-bending area; another insulating film disposed on the wiring line; a connection line which is disposed on another insulating film of the non-bending area and has a first contact area connected to the wiring line; a first planarization layer disposed on the connection line; a link line which is disposed on the first planarization layer to extend to the bending area and has a second contact area connected to the connection line; a second planarization layer which is disposed on the link line and includes an open area formed by removing a partial area to expose the second contact area of the link line; and still another insulating film which is disposed on the second planarization layer and is filled in the open area.

Other detailed matters of the exemplary embodiments are included in the detailed description and the drawings.

According to the present disclosure, a photo-acryl (PAC) based material is applied for the planarization layer to partially remove the planarization layer above a contact hole of the GIP line unit and be filled with a bank formed of polyimide (PI) based material. By doing this, the corrosion defect issue of the GIP line unit can be addressed or minimized while improving the productivity.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIGS. 1A to 1D are plan views schematically illustrating a flexible display device according to an exemplary embodiment of the present disclosure;

FIGS. 2A and 2B are views illustrating a first optical area of a flexible display device of FIGS. 1A to 1D as an example;

FIG. 3 is an equivalent circuit diagram of a sub pixel of a flexible display device according to an exemplary embodiment of the present disclosure;

FIG. 4 is a view illustrating a placement of a sub pixel of a display area in a display panel according to an exemplary embodiment of the present disclosure;

FIG. 5A is a view illustrating a placement of a signal line in a first optical area and a normal area in a display panel according to an exemplary embodiment of the present disclosure;

FIG. 5B is a view illustrating a placement of a signal line in a second optical area and a normal area in a display panel according to an exemplary embodiment of the present disclosure;

FIG. 6 is a view illustrating a cross-sectional structure of a non-transmission area and a transmission area in a first optical area and a cross-sectional structure of a normal area, in a flexible display device according to an exemplary embodiment of the present disclosure;

FIG. 7 is a view illustrating a part of a cross section of a flexible display device according to an exemplary embodiment of the present disclosure;

FIG. 8 is a view illustrating a part of a cross section of a flexible display device according to another exemplary embodiment of the present disclosure;

FIG. 9 is a plan view illustrating a GIP line unit of an exemplary embodiment of the present disclosure;

FIG. 10 is a cross-sectional view taken along the line C-C′ of FIG. 9;

FIG. 11 is a plan view illustrating a first optical area of a flexible display device according to an exemplary embodiment of the present disclosure; and

FIG. 12 is an enlarged view of an area X of FIG. 11.

### DETAILED DESCRIPTION OF THE EMBODIMENTS

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “comprising” used herein are generally intended to allow other components to be added unless the terms are used with the term “only”. Any references to singular can include plural unless expressly stated otherwise. Further, the term “exemplary” is interchangeably used with the term “example” and has the same or similar meaning as the term “example”.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed therebetween unless the term is used with the term “immediately” or “directly”.

Although the terms “first”, “second”, and the like are used for describing various components, these components are not confined by these terms. These terms are merely used for distinguishing one component from the other components, and may not define order or sequence. Therefore, a first component to be mentioned below can be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings. All the components of each display device according to all embodiments of the present disclosure are operatively coupled and configured.

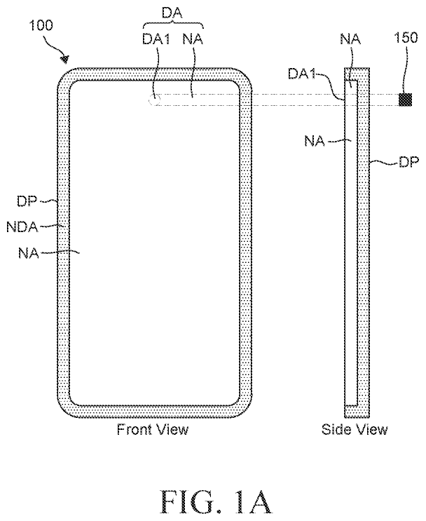

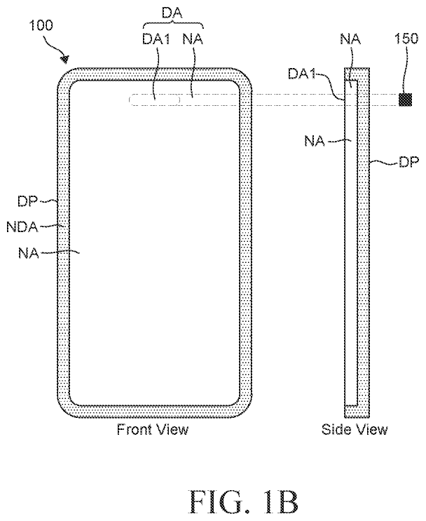

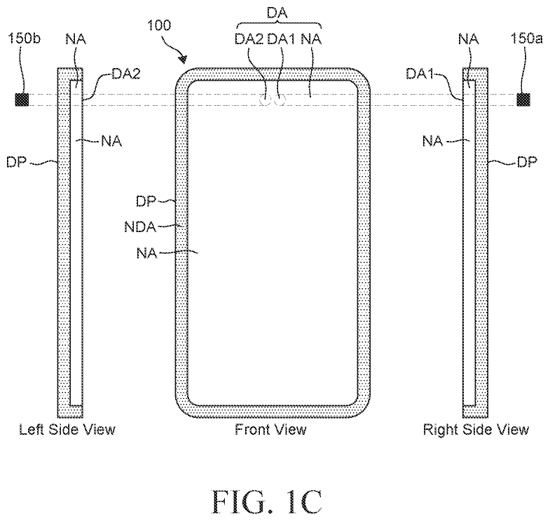

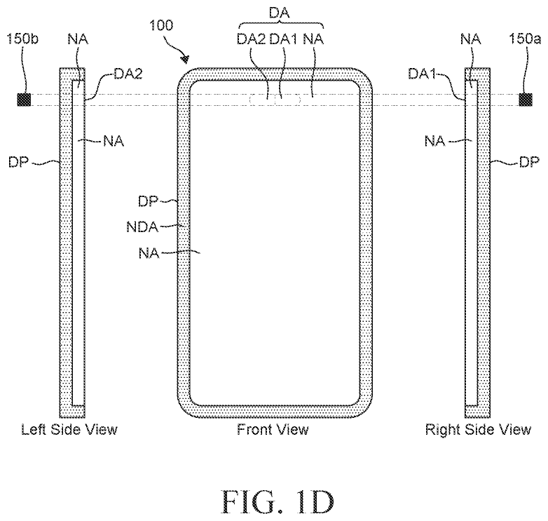

FIGS. 1A to 1D are plan views schematically illustrating a flexible display device according to an exemplary embodiment of the present disclosure.

Referring to FIGS. 1A to 1D, a flexible display device 100 according to an exemplary embodiment of the present disclosure can include a display panel DP which displays images and one or more optical electronic devices 150, 150a, and 150b. The optical electronic devices 150, 150a, and 150b can include a light receiving device which receives light.

The display panel DP is a panel for displaying images to a user.

The display panel DP can include a display element which displays images, a driving element which drives the display element, and wiring lines which transmit various signals to the display element and the driving element. The display element can be defined in different ways depending on a type of the display panel DP. For example, when the display panel DP is an organic light emitting display panel, the display element can be an organic light emitting diode which includes an anode electrode, an organic layer, and a cathode electrode. For example, when the display panel DP is a liquid crystal display panel, the display element can be a liquid crystal display element.

Hereinafter, even though the display panel DP is assumed as an organic light emitting display panel, the display panel DP is not limited to the organic light emitting display panel.

In the meantime, the display panel DP can be configured to include a substrate, and a plurality of insulating films, a transistor layer, and a light emitting diode layer on the substrate. The display panel DP can include a plurality of sub pixels for displaying images and various signal lines for driving the plurality of sub pixels. The signal lines can include a plurality of data lines, a plurality of gate lines, a plurality of power lines, and the like. At this time, each of the plurality of sub pixels can include a transistor located on the transistor layer and a light emitting diode located on the light emitting diode layer.

The display panel DP can include a display area DA and a non-display area NDA. The display area DA is an area where images are displayed in the display panel DP.

In the display area DA, a plurality of sub pixels which forms the plurality of pixels and a circuit for driving the plurality of sub pixels can be disposed. The plurality of sub pixels is minimum units which form the display area DA and a display element can be disposed in each of the plurality of sub pixels. The plurality of sub pixels can form a pixel. For example, an organic light emitting diode which includes an anode electrode, an organic layer, and a cathode electrode can be disposed in each of the plurality of sub pixels, but it is not limited thereto. Further, a circuit for driving the plurality of sub pixels can include a driving element, a wiring line, and the like. For example, the circuit can be configured by a thin film transistor, a storage capacitor, a gate line, and a data line, but is not limited thereto.

The non-display area NDA is an area where no image is displayed. The non-display area NDA can be bent so as not to be seen from a front surface or blocked by a case and is also referred to as a bezel area.

Even though in FIGS. 1A to 1D, it is illustrated that the non-display area NDA encloses a quadrangular display area DA, shapes and placements of the display area DA and the non-display area NDA are not limited to the example illustrated in FIGS. 1A to 1D. For example, the display area DA and the non-display area NDA can have shapes suitable for a design of an electronic device including the flexible display device 100. For example, an exemplary shape of the display area DA can be a pentagon, a hexagon, a circle, an oval, or the like.

In the non-display area NDA, various wiring lines and circuits for driving the organic light emitting diode of the display area DA can be disposed. For example, in the non-display area NDA, a link line which transmits signals to the plurality of sub pixels and circuits of the display area DA, a gate-in-panel (GIP) line, or a driving integrated circuit (IC), such as a gate driver IC or a data driver IC, can be disposed, but it is not limited thereto.

The flexible display device 100 can further include various additional elements to generate various signals or drive the pixel in the display area DA. The additional elements for driving the pixels can include an inverter circuit, a multiplexer, or an electrostatic discharge (ESD) circuit. The flexible display device 100 can further include an additional element associated with a function other than a pixel driving function. For example, the flexible display device 100 can further include additional elements which provide a touch sensing function, a user authentication function (for example, fingerprint recognition), a multilevel pressure sensing function, or a tactile feedback function. The above-mentioned additional elements can be located in an external circuit which is connected to the non-display area NDA and/or the connecting interface.

Referring to FIGS. 1A to 1D, the display area DA can include a first optical area DA1 and a second optical area DA2, but is not limited thereto.

In FIGS. 1A to 1D, one or more optical electronic devices 150, 150a, and 150b are electronic components below (an opposite side of a viewing surface) of the display panel DP.

Light enters the front surface (viewing surface) of the display panel DP and passes through the display panel DP to be transmitted to one or more optical electronic devices 150, 150a, and 150b located below (an opposite side of a viewing surface) of the display panel DP.

One or more optical electronic devices 150, 150a, and 150b can be devices which receive light which passes through the display panel DP to perform a predetermined function according to received light. For example, the optical electronic devices 150, 150a, and 150b can include one or more of an image capturing device such as a camera (image sensor), an illumination sensor, a sensing sensor, and a proximity sensor.

As described above, the optical electronic devices 150, 150a, and 150b are devices which require light reception, but can be disposed behind (below) the display panel DP. For example, the optical electronic devices 150, 150a, and 150b can be located in an opposite side of a viewing surface of the display panel DP. The optical electronic devices 150, 150a, and 150b are not exposed to the front surface of the flexible display device 100. Accordingly, when a user views a front surface of the flexible display device 100, the optical electronic devices 150, 150a, and 150b are not seen.

For example, a camera which is located behind (below) the display panel DP is a front camera which captures the front image and can also be considered as a camera lens.

The optical electronic devices 150, 150a, and 150b can be disposed so as to overlap the display area DA of the display panel DP. For example, the optical electronic devices 150, 150a, and 150b can be disposed in the display area DA.

Referring to FIGS. 1A to 1D, the display area DA can include a normal area NA and one or more optical areas DA1 and DA2. One or more optical areas DA1 and DA2 can be areas overlapping one or more optical electronic devices 150, 150a, and 150b. The normal area NA can be also referred to as a main area for displaying images, which may or may not be a primary area.

According to an example of FIG. 1A, the display area DA can include the normal area NA (main area) and a first optical area DA1. Here, at least a part of the first optical area DA1 can overlap a first optical electronic device 150.

Even though in FIG. 1A, a circular structure of the first optical area DA1 is illustrated, but a shape of the first optical area DA1 according to the exemplary embodiment of the present disclosure is not limited thereto.

For example, as illustrated in FIG. 1B, the first optical area DA1 can have an octagonal shape, and also can be formed of various polygonal shapes.

According to an example of FIG. 1C, the display area DA can include a normal area NA, a first optical area DA1, and a second optical area DA2. In the example of FIG. 1C, the normal area NA can be disposed between the first optical area DA1 and the second optical area DA2. Here, at least a part of the first optical area DA1 can overlap the first optical electronic device 150a and at least a part of the second optical area DA2 can overlap the second optical electronic device 150b.

According to an example of FIG. 1D, the display area DA can include a normal area NA, a first optical area DA1, and a second optical area DA2. In the example of FIG. 1D, the normal area NA is not disposed between the first optical area DA1 and the second optical area DA2. For example, the first optical area DA1 and the second optical area DA2 can be in contact with each other. Here, at least a part of the first optical area DA1 can overlap the first optical electronic device 150a and at least a part of the second optical area DA2 can overlap the second optical electronic device 150b.

In one or more optical areas DA1 and DA2, both an image display structure and a light transmission structure need to be formed. For example, one or more optical areas DA1 and DA2 are a partial area of the display area DA so that in one or more optical areas DA1 and DA2, a sub pixel for displaying an image needs to be disposed. In one or more optical areas DA1 and DA2, a light transmission structure which transmits light to one or more optical electronic devices 150, 150a, and 150b must be formed.

One or more optical electronic devices 150, 150a, and 150b are devices which need to receive light, but are located behind the display panel DP (below, an opposite side of a viewing surface) to receive light which passes through the display panel DP.

One or more optical electronic devices 150, 150a, and 150b are not exposed onto the front surface (the viewing surface) of the display panel DP. Accordingly, when a user views the front surface of the flexible display device 100, the optical electronic devices 150, 150a, and 150b are not seen to the user.

For example, the first optical electronic devices 150 and 150a can be cameras and the second optical electronic device 150b can be a sensing sensor such as a proximity sensor or an illumination sensor. For example, the sensing sensor can be an infrared sensor which senses an infrared ray.

In contrast, the first optical electronic devices 150 and 150a can be sensing sensors and the second optical electronic device 150b can be a camera.

Hereinafter, for the convenience of description, an example that the first optical electronic devices 150 and 150a are cameras and the second optical electronic device 150b is a sensing sensor will be described. Here, the camera can be a camera lens or an image sensor.

When the first optical electronic devices 150 and 150a are cameras, the camera can be a front side camera which is located behind (below) the display panel DP, but captures a front direction of the display panel DP. Accordingly, a user can take a picture through a camera which is not seen from the viewing surface while watching the viewing surface of the display panel DP.

The normal area NA and one or more optical areas DA1 and DA2 included in the display area DA are areas in which images can be displayed. The normal area NA is an area in which there is no need to form a light transmission structure and one or more optical areas DA1 and DA2 are areas in which the light transmission structure needs to be formed.

Accordingly, one or more optical areas DA1 and DA2 need to have a predetermined level or higher of transmittance and the normal area NA does not have light transmissivity or has a transmittance lower than a predetermined level.

For example, one or more optical areas DA1 and DA2 and the normal area NA can have different resolutions, sub pixel placement structures, numbers of sub pixels for every unit area, electrode structures, line structures, electrode placement structures, or line placement structures.

For example, the number of sub pixels for every unit area in one or more optical areas DA1 and DA2 can be smaller than the number of sub pixels for every unit area in the normal area NA. For example, the resolution of one or more optical areas DA1 and DA2 can be lower than a resolution of a normal area NA. At this time, the number of sub pixels for every unit area is a unit of measuring a resolution and can be also pixels per inch (PPI) indicating the number of pixels within one inch.

For example, the number of sub pixels for every unit area in the first optical area DA1 can be smaller than the number of sub pixels for every unit area in the normal area NA. The number of sub pixels for every unit area in the second optical area DA2 can be larger than the number of sub pixels for every unit area in the first optical area DA1.

The first optical area DA1 can have various shapes such as a circle, an oval, a rectangle, a hexagon, or an octagon. The second optical area DA2 can have various shapes such as a circle, an oval, a rectangle, a hexagon, or an octagon. The first optical area DA1 and the second optical area DA2 can have the same shape or different shapes.

Referring to FIG. 1D, when the first optical area DA1 and the second optical area DA2 are in contact with each other, the entire optical area including the first optical area DA1 and the second optical area DA2 can have various shapes, such as a circle, an oval, a rectangle, a hexagon, or an octagon.

Hereinafter, for the convenience of description, an example that the first optical area DA1 and the second optical area DA2 are circles will be described.

In the flexible display device 100 according to the exemplary embodiment of the present disclosure, when the first optical electronic device 150 and 150a which are not exposed to the outside and are hidden below the display panel DP are cameras, the flexible display device 100 according to the exemplary embodiment of the present disclosure can be said as a display to which a under display camera (UDC) technique is applied.

By doing this, in the flexible display device 100 according to the exemplary embodiment of the present disclosure, there is no need to form a notch or a camera hole for exposing the camera in the display panel DP, so that the area of the display area DA is not reduced.

Accordingly, there is no need to form a notch or a camera hole for exposing the camera in the display panel DP so that a size of the bezel area is reduced and design constraints are not provided to increase a degree of freedom of design.

In the flexible display device 100 according to the exemplary embodiment of the present disclosure, even though one or more optical electronic devices 150, 150a, and 150b are hidden behind the display panel DP, one or more optical electronic devices 150, 150a, and 150b need to normally receive the light to normally perform a determined function.

Further, in the flexible display device 100 according to the exemplary embodiment of the present disclosure, even though one or more optical electronic devices 150, 150a, and 150b are hidden behind the display panel DP and overlap the display area DA, in one or more optical areas DA1 and DA2 overlapping one or more optical electronic devices 150, 150a, and 150b in the display area DA, the image needs to be normally displayed.

Accordingly, the flexible display device 100 according to the exemplary embodiment of the present disclosure can have a structure which improves a transmittance of the first and second optical areas DA1 and DA2 overlapping the optical electronic devices 150, 150a, and 150b.

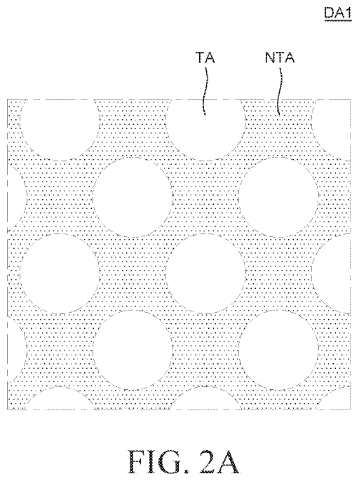

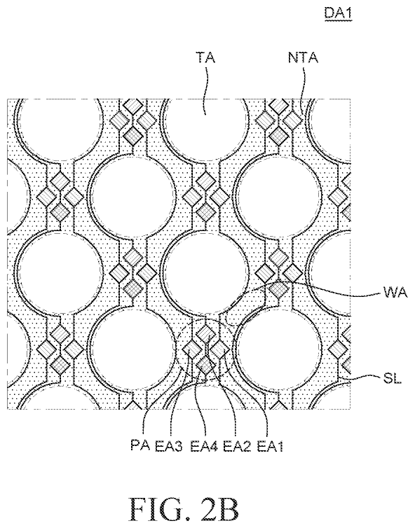

FIGS. 2A and 2B are views illustrating a first optical area of a flexible display device of FIGS. 1A to 1D as an example.

As compared with FIG. 2A, in FIG. 2B, a wiring line SL and emission areas EA1, EA2, EA3, and EA4 of the sub pixel are additionally illustrated.

Referring to FIGS. 2A and 2B, the first optical area DA1 can overlap the optical electronic device. The first optical area DA1 can include a non-transmission area NTA and a transmission area TA.

The transmission area TA is a partial area which is included in the first optical area DA1 and as an opaque configuration, such as the cathode electrode, is removed, external light can be transmitted to the optical electronic device. For example, the transmission area TA can have a circular or oval shape, and can be also referred to as a hole area.

Further, the non-transmission area NTA is a partial area included in the first optical area DA1 and a transistor of the transistor layer and a light emitting diode of the light emitting diode layer can be disposed in the non-transmission area.

The non-transmission area NTA includes a pixel area PA in which emission areas EA1, EA2, EA3, and EA4 of a plurality of sub pixels are disposed and a wiring area WA in which a signal line SL is disposed.

When the transmission area TA is enclosed by the non-transmission area NTA, the first optical area DA1 can include a plurality of separated transmission areas TA, but is not limited thereto.

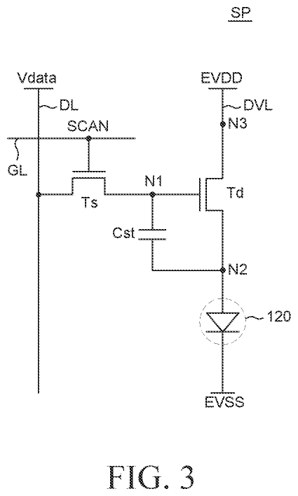

FIG. 3 is an equivalent circuit diagram of a sub pixel of a flexible display device according to an exemplary embodiment of the present disclosure.

Referring to FIG. 3, in the flexible display device according to the exemplary embodiment of the present disclosure, each of the plurality of sub pixels SP disposed in the display panel can include a light emitting diode 120, a driving transistor Td, a scan transistor Ts, a storage capacitor Cst, and the like.

At this time, the light emitting diode 120 can include a pixel electrode, a common electrode, and an emission layer located between the pixel electrode and the common electrode. The pixel electrode is disposed in each sub pixel SP and the common electrode can be commonly disposed in the plurality of sub pixels SP. For example, the pixel electrode is an anode electrode and the common electrode can be a cathode electrode. As another example, the pixel electrode is a cathode electrode and the common electrode can be an anode electrode. For example, the light emitting diode 120 can be an organic light emitting diode OLED, a micro light emitting diode (Micro LED), a quantum dot (QD) light emitting diode, or the like.

The driving transistor Td is a transistor for driving the light emitting diode 120 and can include a first node N1, a second node N2, and a third node N3.

The first node N1 of the driving transistor Td can be a gate node of the driving transistor Td and can be electrically connected to a source node or a drain node of the scan transistor Ts. Further, the second node N2 of the driving transistor Td is a source node or a drain node of the driving transistor Td and can be electrically connected to the pixel electrode of the light emitting diode 120. The third node N3 of the driving transistor Td is electrically connected to a driving voltage line DVL which supplies a driving voltage EVDD.

Further, the scan transistor Ts is controlled by a scan signal SCAN and can be connected between the first node N1 of the driving transistor Td and the data line DL. The scan transistor Ts is turned on or turned off in accordance with the scan signal SCAN supplied from the gate line GL to control connection between the data line DL and the first node N1 of the driving transistor Td.

The scan transistor Ts is turned on by the scan signal SCAN having a turn-on level voltage to transmit a data voltage Vdata supplied from the data line DL to the first node N1 of the driving transistor Td.

The turn-on level voltage of the scan signal SCAN which turns on the scan transistor Ts can be a high level voltage or a low level voltage. The turn-off level voltage of the scan signal SCAN which turns off the scan transistor Ts can be a low level voltage or a high level voltage. For example, when the scan transistor Ts is a n-type transistor, the turn-on level voltage is a high level voltage and the turn-off level voltage can be a low level voltage. As another example, when the scan transistor Ts is a p-type transistor, the turn-on level voltage is a low level voltage and the turn-off level voltage can be a high level voltage.

Each of the driving transistor Td and the scan transistor Ts can be an n-type transistor or a p-type transistor.

The storage capacitor Cst can be connected between the first node N1 and the second node N2 of the driving transistor Td. The storage capacitor Cst is charged with a quantity of charges corresponding to a voltage difference of both ends of the storage capacitor Cst and maintains a voltage difference of both ends during a predetermined frame time. Accordingly, during the predetermined frame time, a corresponding sub pixel SP can emit light.

The storage capacitor Cst can be an external capacitor which is intentionally designed at the outside of the driving transistor Td, rather than a parasitic capacitor which is an internal capacitor present between the gate node and the source node (or the drain node) of the driving transistor Td.

A sub pixel SP of the flexible display device according to the exemplary embodiment of the present disclosure further includes one or more transistors or can further include one or more capacitors.

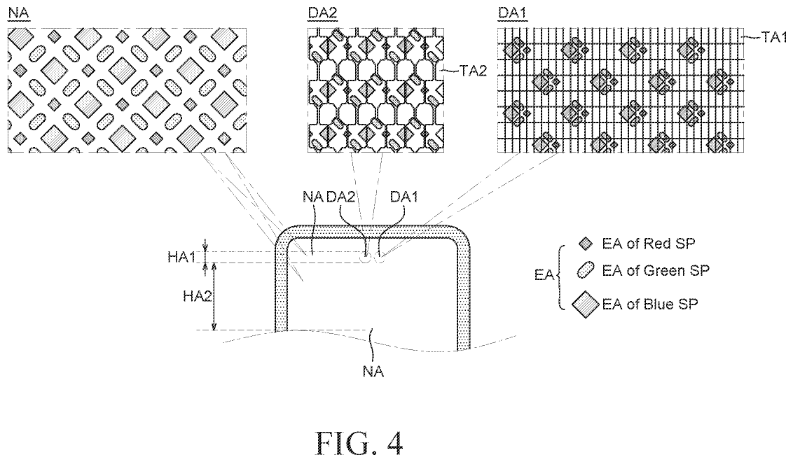

FIG. 4 is a view illustrating a placement of a sub pixel of a display area in a display panel according to an exemplary embodiment of the present disclosure.

More specifically, FIG. 4 illustrates the placement of the sub pixels SP in three areas NA, DA1, and DA2 included in the display area of the display panel according to the exemplary embodiment of the present disclosure.

Referring to FIG. 4, in the normal area NA, the first optical area DA1, and the second optical area DA2 included in the display area, a plurality of sub pixels SP can be disposed.

For example, the plurality of sub pixels SP can include a red sub pixel Red SP which emits red light, a green sub pixel Green SP which emits green light, and a blue sub pixel Blue SP which emits blue light.

Therefore, each of the normal area NA, the first optical area DA1, and the second optical area DA2 can include an emission area EA of the red sub pixel Red SP, an emission area EA of the green sub pixel Green SP, and an emission area EA of the blue sub pixel Blue SP.

Referring to FIG. 4, the normal area NA does not include a light transmission structure, but include an emission area EA. However, the first optical area DA1 and the second optical area DA2 need to include not only the emission area EA, but also the light transmission structure.

Accordingly, the first optical area DA1 can include the emission area EA and a first transmission area TA1 and the second optical area DA2 can include the emission area EA and a second transmission area TA2.

The emission area EA and the transmission areas TA1 and TA2 can be distinguished depending on whether to transmit light. For example, the emission area EA can be an area through which the light may not be transmitted and the transmission areas TA1 and TA2 can be an area through which the light can be transmitted.

Further, the emission area EA and the transmission areas TA1 and TA2 can be distinguished depending on whether to form a specific metal layer. For example, in the emission area EA, the cathode electrode is formed and in the transmission areas TA1 and TA2, the cathode electrode may not be formed. Further, in the emission area EA, a light shielding layer is formed and in the transmission areas TA1 and TA2, the light shielding layer may not be formed.

At this time, the first optical area DA1 includes a first transmission area TA1 and the second optical area DA2 includes a second transmission area TA2 so that both the first optical area DA1 and the second optical area DA2 are areas through which light can pass.

At this time, a transmittance (degree of transmission) of the first optical area DA1 and a transmittance (a degree of transmission) of the second optical area DA2 can be equal.

In this case, the first transmission area TA1 of the first optical area DA1 and the second transmission area TA2 of the second optical area DA2 can have the same shape or same size. Alternatively, even though the first transmission area TA1 of the first optical area DA1 and the second transmission area TA2 of the second optical area DA2 have different shapes or sizes, a transmittance of the first transmission area TA1 in the first optical area DA1 and a transmittance of the second transmission area TA2 in the second optical area DA2 can be equal.

In contrast, a transmittance (a degree of transmission) of the first optical area DA1 and a transmittance (a degree of transmission) of the second optical area DA2 can be different from each other.

In this case, the first transmission area TA1 of the first optical area DA1 and the second transmission area TA2 of the second optical area DA2 can have different shapes or sizes. Alternatively, even though the first transmission area TA1 of the first optical area DA1 and the second transmission area TA2 of the second optical area DA2 have the same shape or size, a transmittance of the first transmission area TA1 in the first optical area DA1 and a transmittance of the second transmission area TA2 in the second optical area DA2 can be different.

For example, when the first optical electronic device which overlaps the first optical area DA1 is a camera and the second optical electronic device which overlaps the second optical area DA2 is a sensing sensor, the camera can require more amount of light than the sensing sensor.

Accordingly, the transmittance (a degree of transmission) of the first optical area DA1 can be higher than the transmittance (a degree of transmission) of the second optical area DA2.

In this case, the size of the first transmission area TA1 of the first optical area DA1 can be larger than the size of the second transmission area TA2 of the second optical area DA2. Alternatively, even though the first transmission area TA1 of the first optical area DA1 and the second transmission area TA2 of the second optical area DA2 have the same shape or size, a transmittance of the first transmission area TA1 in the first optical area DA1 can be higher than a transmittance of the second transmission area TA2 in the second optical area DA2.

Hereinafter, for the convenience of description, an example that the transmittance (a degree of transmission) of the first optical area DA1 is higher than the transmittance (a degree of transmission) of the second optical area DA2 will be described.

Further, as illustrated in FIG. 4, in the exemplary embodiment of the present disclosure, the transmission areas TA1 and TA2 can also be referred to as transparent areas and the transmittance is also referred to as a transparency.

Further, as illustrated in FIG. 4, in the exemplary embodiment of the present disclosure, it is assumed that the first optical area DA1 and the second optical area DA2 are located in an upper portion of the display area of the display panel and are horizontally aligned with each other.

Referring to FIG. 4, a horizontal display area in which the first optical area DA1 and the second optical area DA2 are disposed is referred to as a first horizontal display area HA1. Further, a horizontal display area in which the first optical area DA1 and the second optical area DA2 are not disposed is referred to as a second horizontal display area HA2.

Referring to FIG. 4, the first horizontal display area HA1 can include the normal area NA, the first optical area DA1, and the second optical area DA2. In contrast, the second horizontal display area HA2 can include only the normal area NA.

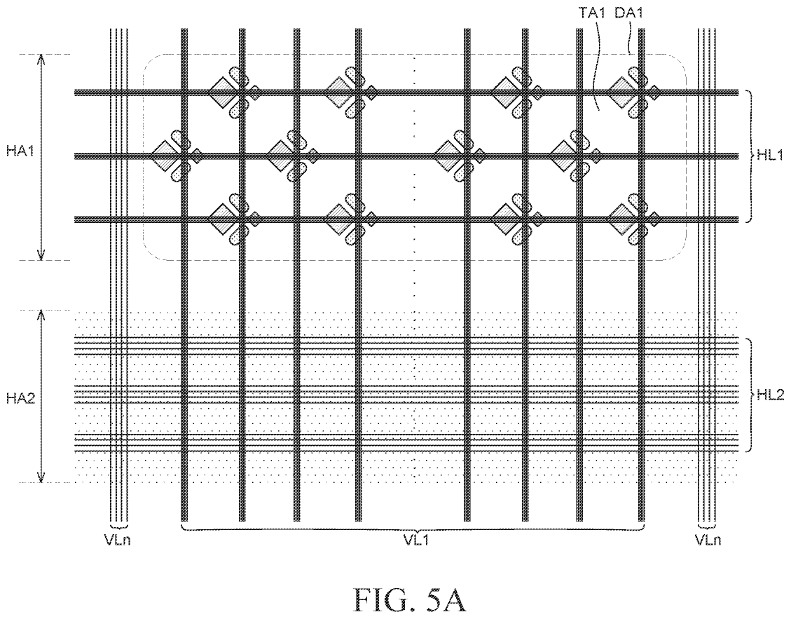

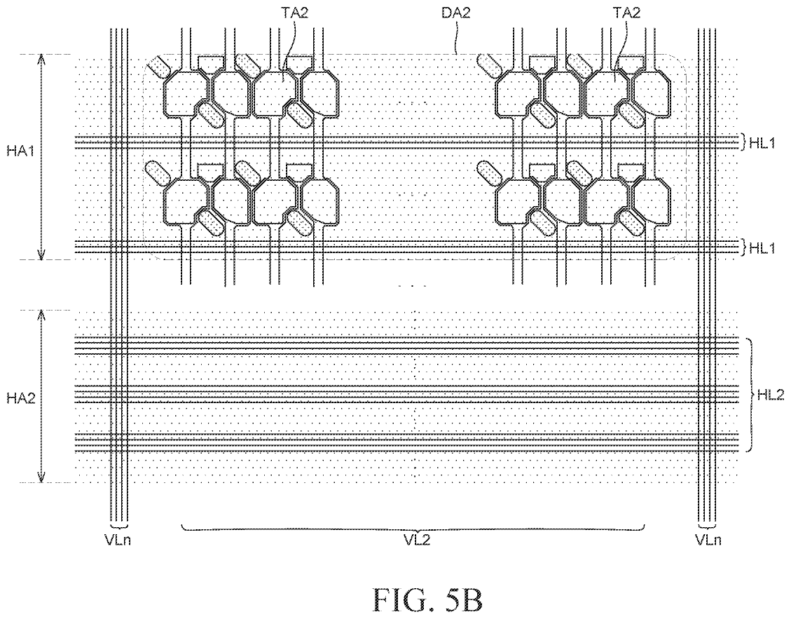

FIG. 5A is a view illustrating a placement of a signal line in a first optical area and a normal area in a display panel according to an exemplary embodiment of the present disclosure.

FIG. 5B is a view illustrating a placement of a signal line in a second optical area and a normal area in a display panel according to an exemplary embodiment of the present disclosure.

More specifically, FIG. 5A illustrates the placement of the signal line in the first optical area DA1 and the normal area in the display panel according to the exemplary embodiment of the present disclosure. FIG. 5B illustrates the placement of the signal line in the second optical area DA2 and the normal area in the display panel according to the exemplary embodiment of the present disclosure.

The first horizontal display area HA1 illustrated in FIGS. 5A and 5B is a part of the first horizontal display area HA1 in the display panel and the second horizontal display area HA2 is a part of the second horizontal display area HA2 in the display panel.

The first optical area DA1 illustrated in FIG. 5A is a part of the first optical area DA1 in the display panel and the second optical area DA2 illustrated in FIG. 5B is a part of the second optical area DA2 in the display panel.

Referring to FIGS. 5A and 5B, the first horizontal display area HA1 can include the normal area, the first optical area DA1, and the second optical area DA2. The second horizontal display area HA2 can include the normal area.

In the display panel, various types of horizontal lines HL1 and HL2 are disposed and various types of vertical lines VLn, VL1, and VL2 can be disposed.

In the exemplary embodiment of the present disclosure, the horizontal direction and the vertical direction refer to two intersecting directions and the horizontal direction and the vertical direction can vary according to a viewing direction. For example, in the exemplary embodiment of the present disclosure, the horizontal direction refers to a direction in which one gate line extends and the vertical direction refers to a direction in which one data line extends. As described above, the horizontal and the vertical are exemplified and other variations are possible.

Referring to FIGS. 5A and 5B, the horizontal line disposed in the display panel can include a first horizontal line HL1 disposed in the first horizontal display area HA1 and a second horizontal line HL2 disposed in the second horizontal display area HA2.

The horizontal line disposed in the display panel can be a gate line. For example, the first horizontal line HL1 and the second horizontal line HL2 can be gate lines. The gate line can include various types of gate line depending on the structure of the sub pixel.

Referring to FIGS. 5A and 5B, the vertical line disposed in the display panel can include a normal vertical line VLn disposed only in the normal area, a first vertical line VL1 which passes through both the first optical area DA1 and the normal area and a second vertical line VL2 which passes through both the second optical area DA2 and the normal area.

The vertical line disposed in the display panel can include a data line and a driving voltage line and further can include a reference voltage line and an initialization voltage line. For example, the normal vertical line VLn, the first vertical line VL1, and the second vertical line VL2 can include not only a data line and a driving voltage line but also a reference voltage line and an initialization voltage line.

In the exemplary embodiment, the term “horizontal” in the second horizontal line HL2 means that the signal is transmitted from a left side (or right side) to a right side (or left side), but does not mean that the second horizontal line HL2 straightly extends only in the exact horizontal direction. For example, in FIGS. 5A and 5B, the second horizontal line HL2 is illustrated as a straight line, but the second horizontal line HL2 can include a bent or curved portion. Similarly, the first horizontal line HL1 also can include a bent or curved portion.

In the exemplary embodiment, the term “vertical” in the normal vertical line VLn means that the signal is transmitted from an upper side (or lower side) to a lower side (or upper side), but does not mean that the normal vertical line VLn straightly extends only in the exact vertical direction. For example, in FIGS. 5A and 5B, the normal vertical line VLn is illustrated as a straight line, but the normal vertical line VLn can include a bent or curved portion. Similarly, the first vertical line VL1 and the second vertical line VL2 can include a bent or curved portion.

Referring to FIG. 5A, the first optical area DA1 included in the first horizontal area HA1 can include an emission area and a first transmission area. In the first optical area DA1, an external area of the first transmission area can include the emission area.

In order to improve the transmittance of the first optical area DA1, the first horizontal line HL1 which passes through the first optical area DA1 can avoid the first transmission area in the first optical area DA1.

Accordingly, the first horizontal line HL1 which passes through the first optical area DA1 can include a curved section or a bending section which detours outside of an outer edge of the first transmission area.

Accordingly, the first horizontal line HL1 disposed in the first horizontal area HA1 and the second horizontal line HL2 disposed in the second horizontal area HA2 can have different shapes or lengths. For example, the first horizontal line HL1 which passes through the first optical area DA1 and the second horizontal line HL2 which does not pass through the first optical area DA1 can have different shapes or lengths.

Further, in order to improve the transmittance of the first optical area DA1, the first vertical line VL1 which passes through the first optical area DA1 can avoid the first transmission area in the first optical area DA1.

The first vertical line VL1 which passes through the first optical area DA1 can include a curved section or a bending section which detours outside of an outer edge of the first transmission area.

Accordingly, the first vertical line VL1 which passes through the first optical area DA1 and the normal vertical line VLn which does not pass through the first optical area DA1 and is disposed in the normal area can have different shapes or lengths.

Referring to FIG. 5A, the first transmission area included in the first optical area DA1 in the first horizontal area HA1 can be diagonally disposed.

The emission area can be disposed between two first transmission areas which are adjacent to each other in the left and right in the first optical area DA1 in the first horizontal area HA1. The emission area can be disposed between two first transmission areas which are adjacent to each other up and down in the first optical area DA1 in the first horizontal area HA1.

The first horizontal line HL1 disposed in the first horizontal area HA1, for example, the first horizontal line HL1 which passes through the first optical area DA1 can include at least one of curved area or a bending area which detours the outside of the outer edge of the first transmission area.

Referring to FIG. 5B, the second optical area DA2 included in the first horizontal area HA1 includes an emission area and a second transmission area TA2. In the second optical area DA2, an outside area of the second transmission area TA2 can include the emission area.

The location and the placement state of the emission area and the second transmission area TA2 in the second optical area DA2 can be the same as the location and the placement state of the emission area and the second transmission area in the first optical area DA1 in FIG. 5A.

In contrast, as illustrated in FIG. 5B, the location and the placement state of the emission area and the second transmission area TA2 in the second optical area DA2 can be different from the location and the placement state of the emission area and the second transmission area in the first optical area DA1 in FIG. 5A.

For example, referring to FIG. 5B, in the second optical area DA2, the second transmission area TA2 can be disposed in the horizontal direction (left-right direction). The emission area may not be disposed between two second transmission areas TA2 adjacent in the horizontal direction (left-right direction). Further, the emission area in the second optical area DA2 can be disposed between the second transmission areas TA2 adjacent in the vertical direction (up and down direction). For example, the emission area can be disposed between two second transmission area TA2 rows.

When the first horizontal line HL1 passes through the second optical area DA2 in the first horizontal area HA1 and the normal area therearound, the first horizontal line can pass through in the same manner as illustrated in FIG. 5A.

In contrast, as illustrated in FIG. 5B, when the first horizontal line HL1 passes through the second optical area DA2 in the first horizontal area HA1 and the normal area therearound, the first horizontal line can pass through in the different manner from that illustrated in FIG. 5A.

For example, this is because the location and the placement state of the emission area and the second transmission area TA2 in the second optical area DA2 of FIG. 5B are different from the location and the placement state of the emission area and the second transmission area in the first optical area DA1 in FIG. 5A.

Referring to FIG. 5B, when the first horizontal line HL1 passes through the second optical area DA2 in the first horizontal area HA1 and the normal area therearound, the first horizontal line HL1 can straightly pass between the second transmission areas TA2 adjacent in the vertical direction without a curved section or a bending section.

In other words, one first horizontal line HL1 has a curved section or a bending section in the first optical area DA1, but does not have a curved section or a bending section in the second optical area DA2.

In order to improve the transmittance of the second optical area DA2, the second vertical line VL2 which passes through the second optical area DA2 can avoid the second transmission area TA2 in the second optical area DA2.

Accordingly, the second vertical line VL2 which passes through the second optical area DA2 can include a curved section or a bending section which detours outside an outer edge of the second transmission area TA2.

Accordingly, the second vertical line VL2 which passes through the second optical area DA2 and the normal vertical line VLn which does not pass through the second optical area DA2 and is disposed in the normal area can have different shapes or lengths.

As illustrated in FIG. 5A, the first horizontal line HL1 which passes through the first optical area DA1 can have curved sections or bending sections which detour the outside of the outer edge of the first transmission area.

As such, a length of the first horizontal line HL1 which passes through the first optical area DA1 and the second optical area DA2 can be slightly longer than a length of the second horizontal line HL2 which is disposed only in the normal area without passing through the first optical area DA1 and the second optical area DA2.

Accordingly, a resistance of the first horizontal line HL1 which passes through the first optical area DA1 and the second optical area DA2 can be slightly high than a resistance of the second horizontal line HL2 which is disposed only in the normal area without passing through the first optical area DA1 and the second optical area DA2. Hereinafter, the resistance of the first horizontal line HL1 is also referred to as a first resistance and the resistance of the second horizontal line HL2 is also referred to as a second resistance.

Referring to FIGS. 5A and 5B, according to the light transmission structure, the first optical area DA1 which at least partially overlaps the first optical electronic device includes a plurality of first transmission areas TA1. The second optical area DA2 which at least partially overlaps the second optical electronic device includes a plurality of second transmission areas TA2. Accordingly, the number of sub pixels for every unit area of the first optical area DA1 and the second optical area DA2 can be smaller than that of the normal area.

The number of sub pixels which are connected to the first horizontal line HL1 which passes through the first optical area DA1 and the second optical area DA2 can be different from the number of sub pixels which are connected to the second horizontal line HL2 which is disposed only in the normal area without passing through the first optical area DA1 and the second optical area DA2.

The number (first number) of sub pixels which are connected to the first horizontal line HL1 which passes through the first optical area DA1 and the second optical area DA2 can be smaller than the number (second number) of sub pixels which are connected to the second horizontal line HL2 which is disposed only in the normal area without passing through the first optical area DA1 and the second optical area DA2.

The difference between the first number and the second number can vary depending on the difference of a resolution of each of the first optical area DA1 and the second optical area DA2 and a resolution of the normal area. For example, the larger the difference of a resolution of each of the first optical area DA1 and the second optical area DA2 and a resolution of the normal area, the larger the difference between the first number and the second number.

As described above, the number (first number) of sub pixels which are connected to the first horizontal line HL1 which passes through the first optical area DA1 and the second optical area DA2 is smaller than the number (second number) of sub pixels which are connected to the second horizontal line HL2 which is disposed only in the normal area without passing through the first optical area DA1 and the second optical area DA2. Therefore, an area of the first horizontal line HL1 which overlaps the other surrounding electrodes or lines can be smaller than an area of the second horizontal line HL2 which overlaps the other surrounding electrodes or lines.

Accordingly, a parasitic capacitance (hereinafter, a first capacitance) formed by the first horizontal line HL1 and the other surrounding electrodes or lines can be much smaller than a parasitic capacitance (hereinafter, a second capacitance) formed by the second horizontal line HL2 and the other surrounding electrodes or lines.

In consideration of a magnitude relationship of the first resistance and the second resistance (first resistance≥second resistance) and a magnitude relationship of the first capacitance and the second capacitance (first capacitance<<second capacitance), a resistance-capacitance (RC) value (hereinafter, first RC value) of the first horizontal line HL1 which passes through the first optical area DA1 and the second optical area DA2 can be much smaller than a RC value (hereinafter, second RC value) of the second horizontal line HL2 which is disposed only in the normal area without passing through the first optical area DA1 and the second optical area DA2 (first RC value<<second RC value).

A signal transmission characteristic through the first horizontal line HL1 and a signal transmission characteristic through the second horizontal line HL2 can vary due to the difference (hereinafter, referred to as a RC load deviation) between the first RC value of the first horizontal line HL1 and the second RC value of the second horizontal line HL2.

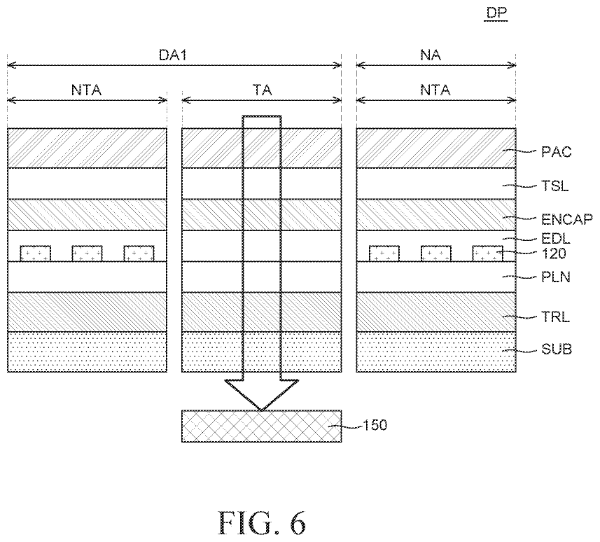

FIG. 6 is a view illustrating a cross-sectional structure of a non-transmission area and a transmission area in a first optical area and a cross-sectional structure of a normal area, in a flexible display device according to an exemplary embodiment of the present disclosure.

Referring to FIG. 6, the first optical area DA1 of the display panel DP can include a transmission area TA and a non-transmission area NTA. The normal area NA of the display panel DP is considered as a non-transmission area NTA.

Hereinafter, a lamination structure of the non-transmission area NTA and a lamination structure of the transmission area TA of the first optical area DA1 and a lamination structure of the normal area NA will be described.

First, the lamination structure of the normal area NA is as follows.

In the normal area NA, a transistor layer TRL is disposed above the substrate SUB and a planarization layer PLN can be disposed above the transistor layer TRL. Further, a light emitting diode layer EDL is disposed above the planarization layer PLN, an encapsulation layer ENCAP is disposed above the light emitting diode layer EDL, a touch sensor layer TSL is disposed above the encapsulation layer ENCAP, and a protection layer PAC can be disposed above the touch sensor layer TSL.

In the normal area NA, on the transistor layer TRL, various transistors, such as a driving transistor and a scan transistor for each sub pixel can be disposed and further various insulating films for forming the transistors can be disposed. Various insulating films include organic films and inorganic films.

In the normal area NA, various wiring lines, such as a data line, a gate line, or a driving voltage line, can be disposed on the transistor layer TRL.

In the normal area, a light emitting diode 120 for each sub pixel can be disposed on the light emitting diode layer EDL. For example, in the normal area NA, a pixel electrode, an emission layer, and a common electrode which form the light emitting diode 120 can be disposed on the light emitting diode layer EDL.

In the normal area NA, on the touch sensor layer TSL, a touch sensor can be disposed and a touch buffer film and a touch insulating film required to form the touch sensor are further disposed.

Next, the lamination structure of the non-transmission area NTA of the first optical area DA1 is the same as the lamination structure of the normal area NA.

Referring to FIG. 6, in the non-transmission area NTA of the first optical area DA1, a transistor layer TRL is disposed above the substrate SUB and a planarization layer PLN can be disposed above the transistor layer TRL. Further, the light emitting diode layer EDL is disposed above the planarization layer PLN, and the encapsulation layer ENCAP can be disposed above the light emitting diode layer EDL. The touch sensor layer TSL is disposed above the encapsulation layer ENCAP and the protection layer PAC can be disposed above the touch sensor layer TSL.

The light emitting diode 120 is vulnerable to moisture or oxygen. The encapsulation layer ENCAP suppresses the permeation of moisture or oxygen to suppress the light emitting diode 120 from being exposed to the moisture or oxygen. The encapsulation layer ENCAP can be formed by one layer or a plurality of layers.

In the non-transmission area NTA of the first optical area DA1, on the transistor layer TRL, various transistors, such as a driving transistor and a scan transistor for each sub pixel can be disposed and further various insulating films for forming the transistors can be disposed. Here, various insulating films include organic films and inorganic films.

Further, in the non-transmission area NTA of the first optical area DA1, various wiring lines, such as a data line, a gate line, or a driving voltage line, can be disposed on the transistor layer TRL.

In the non-transmission area NTA of the first optical area DA1, on the light emitting diode layer EDL, the light emitting diode 120 of each sub pixel can be disposed. For example, in the non-transmission area NTA of the first optical area DA1, a pixel electrode, an emission layer, and a common electrode which form the light emitting diode 120 can be disposed on the light emitting diode layer EDL.

Further, in the non-transmission area NTA of the first optical area DA1, the touch sensor Ts can be disposed on the touch sensor layer TSL and a touch buffer film and a touch insulating film required to form the touch sensor Ts can be further disposed.

The lamination structure of the transmission area TA of the first optical area DA1 is as follows.

Referring to FIG. 6, in the transmission area TA of the first optical area DA1, a transistor layer TRL is disposed above the substrate SUB and a planarization layer PLN can be disposed above the transistor layer TRL. Further, the light emitting diode layer EDL is disposed above the planarization layer PLN, and the encapsulation layer ENCAP can be disposed above the light emitting diode layer EDL. The touch sensor layer TSL is disposed above the encapsulation layer ENCAP and the protection layer PAC can be disposed above the touch sensor layer TSL.

In the transmission area TA of the first optical area DA1, various transistors such as a driving transistor and a scan transistor of each sub pixel and various wiring lines can be disposed on the transistor layer TRL and the light emitting diode 120 for each sub pixel can be disposed on the light emitting diode layer EDL. In the transmission area TA of the first optical area DA1, the touch sensor Ts can be disposed on the touch sensor layer TSL.

At this time, in the transmission area TA of the first optical area DA1, a transistor and a wiring line are not disposed on the transistor layer TRL. However, in the transmission area TA of the first optical area DA1, various insulating films required to form the transistor can be disposed on the transistor layer TRL. Here, various insulating films can include organic films and inorganic films.

Further, in the transmission area TA of the first optical area DA1, the light emitting diode 120 of each sub pixel is not disposed on the light emitting diode layer EDL. For example, in the transmission area TA of the first optical area DA1, the pixel electrode, the emission layer, and the common electrode are not disposed on the light emitting diode layer EDL. However, the present disclosure is not limited thereto and in the transmission area TA of the first optical area DA1, only some of the pixel electrode, the emission layer, and the common electrode can be disposed on the light emitting diode layer EDL. For example, in the transmission area TA of the first optical area DA1, only the emission layer can be disposed on the light emitting diode layer EDL.

In the transmission area TA of the first optical area DA1, the touch sensor is not disposed on the touch sensor layer TSL. In the transmission area TA of the first optical area DA1, the touch buffer film and the touch insulating film can be disposed on the touch sensor layer TSL.

Referring to FIG. 6, a metal material layer, in the metal material layer and an insulating material layer disposed in the non-transmission areas NTA of the first optical area DA1 and the normal area NA is not disposed in the transmission area TA of the first optical area DA1. However, the insulating material layer, in the metal material layer and an insulating material layer disposed in the non-transmission areas NTA of the first optical area DA1 and the normal area NA extends to the transmission area TA of the first optical area DA1.

In other words, the metal material layer is disposed in the non-transmission area NTA of the first optical area DA1 and the non-transmission area NTA of the normal area NA, but is not disposed in the transmission area TA of the first optical area DA1. The insulating material layer can be commonly disposed in the non-transmission area NTA of the first optical area DA1, the non-transmission area NTA of the normal area NA, and in the transmission area TA of the first optical area DA1, but the present disclosure is not limited thereto.

Further, the transmission area TA of the first optical area DA1 can overlap the first optical electronic device 150 and external light can be transmitted to the first optical electronic device 150 through the transmission area TA of the first optical area DA1. Accordingly, for the normal operation of the first optical electronic device 150, the transmittance of the transmission area TA of the first optical area DA1 needs to be high.

In the meantime, the planarization layer PLN of the first optical area DA1 and the normal area NA can be formed by two layers of a first planarization layer and a second planarization layer and photo-acryl PAC can be applied to improve the productivity. For example, according to the present disclosure, a bezel bending display device is applied to reduce a bezel width, two line layers and two planarization layers are applied, and the PAC is applied to improve productivity. In this case, the galvanic corrosion defect issue can be caused in the source/drain line due to the moisture permeation from the upper portion of the display panel. Specifically, in the GIP line unit in the vicinity of a contact hole adjacent to the bending area, wiring lines on different layers are connected, which may cause heterogeneous contact corrosion issues, for example, Galvanic corrosion. The Galvanic corrosion is corrosion in which when two materials are in contact with each other to be exposed to a corrosion environment, electrons move between the metals due to the potential difference so that a corrosion speed of a metal having a noble potential which is relatively high is reduced and a corrosion speed of metal having an active potential which is relatively low is increased. Therefore, in the related art, as the planarization layer PLN, PI is applied, rather than the PAC. However, in the case of the UDC model or the UDIR model, in order to ensure the transmittance of the transmission area TA, the cathode is removed so that the UV reliability is weakened. Further, when PI is applied for the planarization layer PLN, instead of the PAC, it is vulnerable to pixel shrinkage due to outgas. For example, when the PAC is applied, a pixel shrinkage rate for input quantity is 0%, whereas when the PI is applied, a pixel shrinkage rate for input quantity reaches 100%.

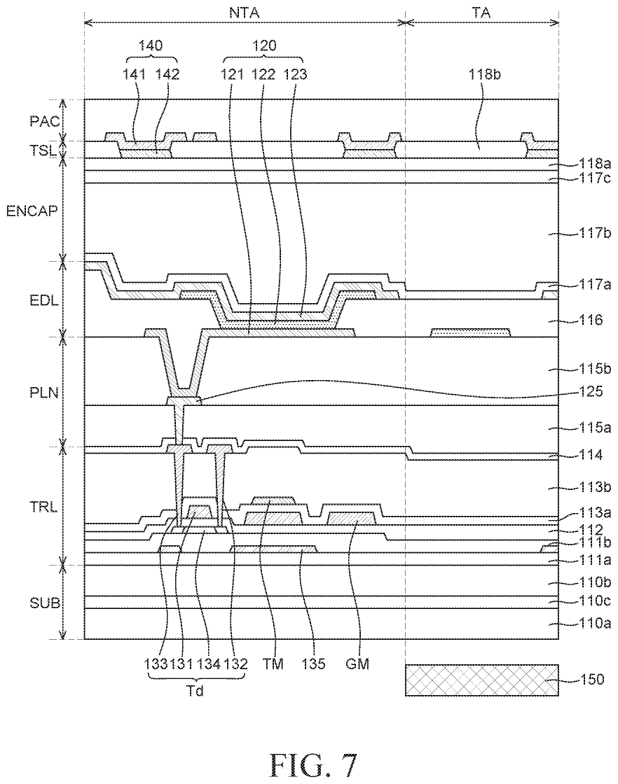

Therefore, according to the present disclosure, a PAC based material is applied for the planarization layer PLN, but a part of the planarization layer PLN above the contact hole of the GIP line unit is removed and is filled with a bank formed of a PI based material or a part of a wiring line above the contact hole of the GIP line unit is covered by a metal layer of the anode electrode or the touch electrode. By doing this, the moisture permeation is suppressed to improve the productivity and eliminate or reduce a galvanic corrosion defect of the GIP line unit. This will be described in detail below with reference to FIGS. 7 to 11.

FIG. 7 is a view illustrating a part of a cross section of a flexible display device according to an exemplary embodiment of the present disclosure.

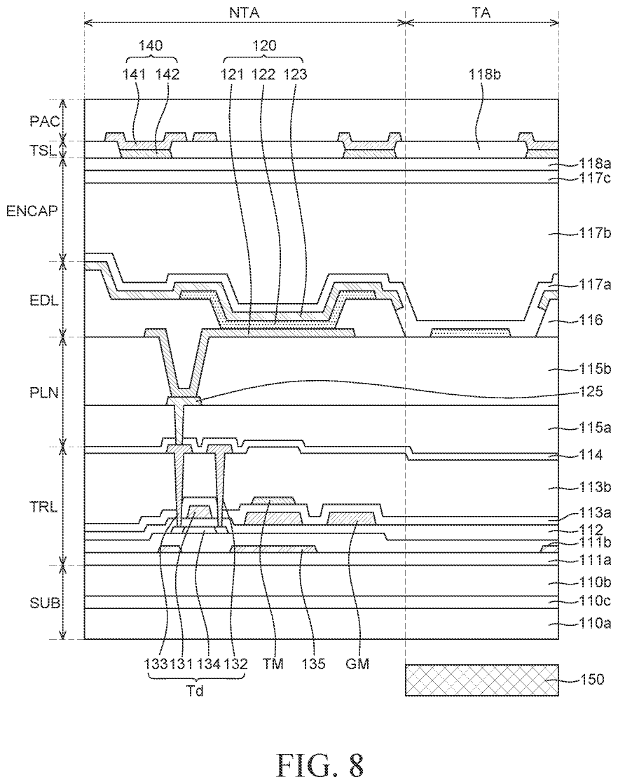

FIG. 8 is a view illustrating a part of a cross section of a flexible display device according to another exemplary embodiment of the present disclosure.

More specifically, FIGS. 7 and 8 illustrate a part of the cross-section of the non-transmission area NTA and the transmission area TA of the first optical area.

In FIG. 7, the bank 116 is disposed in the transmission area TA, but in FIG. 8, a part of the bank 116 in the transmission area TA is removed. For example, in FIGS. 7 and 8, only the shapes of the bank 116 in the transmission area TA are different, but the other configurations are substantially the same so that a redundant description will be omitted.

Referring to FIGS. 7 and 8, both the non-transmission area NTA and the transmission area TA of the first optical area, basically, can include a substrate SUB, a transistor layer TRL, a planarization layer PLN, a light emitting diode layer EDL, an encapsulation layer ENCAP, a touch sensor layer TSL, and a protection layer PAC.

First, the lamination structure of the non-transmission area NTA included in the first optical area will be described.

The substrate SUB can include a first substrate 110a, a second substrate 110b, and an interlayer insulating film 110c. The interlayer insulating film 110c can be disposed between the first substrate 110a and the second substrate 110b. As described above, the substrate SUB is formed by the first substrate 110a, the second substrate 110b, and the interlayer insulating film 110c to suppress the moisture permeation. For example, the first substrate 110a and the second substrate 110b can be polyimide (PI) substrates.

On the transistor layer TRL, various patterns 131, 132, 133, and 134, various insulating films 111a, 111b, 112, 113a, 113b, and 114, and various metal patterns TM, GM, and 135 for forming a transistor, such as a driving transistor Td, can be disposed.

Hereinafter, the lamination structure of the transistor layer TRL will be described in more detail.

A multi-buffer layer 111a is disposed on a second substrate 110b and an active buffer layer 111b can be disposed on the multi-buffer layer 111a. A metal layer 135 can be disposed on the multi-buffer layer 111a. Here, the metal layer 135 can serve as a light shield and is also referred to as a light shielding layer.

An active buffer layer 111b can be disposed on the metal layer 135. An active layer 134 of the driving transistor Td can be disposed on the active buffer layer 111b. A gate insulating film 112 can be disposed on the active layer 134.

Further, a gate electrode 131 of the driving transistor Td can be disposed on the gate insulating film 112. At this time, a gate material layer GM can be disposed on the gate insulating film 112 in a position different of a forming position of the driving transistor Td.

A first interlayer insulating film 113a can be disposed on the gate electrode 131 and the gate material layer GM. A metal pattern TM can be disposed on the first interlayer insulating film 113a. A second interlayer insulating film 113b can be disposed on the first interlayer insulating film 113a while covering the metal pattern TM.

A source electrode 132 and a drain electrode 133 of the driving transistor Td can be disposed on the second interlayer insulating film 113b.

The source electrode 132 and the drain electrode 133 can be connected to one side and the other side of the active layer 134 through contact holes provided in the second interlayer insulating film 113b, the first interlayer insulating film 113a, and the gate insulating film 112.

A part of the active layer 134 which overlaps the gate electrode 131 is a channel region. One of the source electrode 132 and the drain electrode 133 is connected to one side of the channel region in the active layer 134 and the other one is connected to the other side of the channel region in the active layer 134.

The passivation layer 114 can be disposed on the source electrode 132 and the drain electrode 133.

The planarization layer PLN can be located above the transistor layer TRL. The planarization layer PLN can include a first planarization layer 115a and a second planarization layer 115b. The first planarization layer 115a is formed of a PI based material and the second planarization layer 115b can be formed of a PAC based material. For example, the pixel shrinkage issue in the UDC model or the UDIR model is mainly caused by the outgas of the second planarization layer 115b rather than the first planarization 115a so that only the second planarization layer 115b is formed by the PAC based material.

The first planarization layer 115a can be disposed on the passivation layer 114.

The connection electrode 125 can be disposed on the first planarization layer 115a. The connection electrode 125 can be connected to one of the source electrode 132 and the drain electrode 133 through a contact hole provided in the first planarization layer 115a.

The second planarization layer 115b can be disposed on the connection electrode 125. The light emitting diode layer EDL can be located above the second planarization layer 115b.

Hereinafter, a lamination structure of the light emitting diode layer EDL will be described in detail.

The pixel electrode 121 can be disposed on the second planarization layer 115b. At this time, the pixel electrode 121 can be electrically connected to the connection electrode 125 through the contact hole provided in the second planarization layer 115b. For example, the pixel electrode 121 can be an anode electrode.

The bank 116 can be disposed while covering the pixel electrode 121. A part of the bank 116 corresponding to an emission area of the sub pixel can be open. A part of the pixel electrode 121 can be exposed through the open part of the bank 116 (hereinafter, referred to as an open area). At this time, the bank 116 can be formed of a PI based material.

The emission layer 122 can be disposed in the open area of the bank 116 and in the vicinity of the open area of the bank. Therefore, the emission layer 122 can be disposed on the pixel electrode 121 exposed through the open area of the bank 116.

The common electrode 123 can be disposed on the emission layer 122. For example, the common electrode 123 can be a cathode electrode.

The light emitting diode 120 can be formed by the pixel electrode 121, the emission layer 122, and the common electrode 123. The light emitting layer 122 can include a plurality of organic films.

The encapsulation layer ENCAP can be located above the above-described light emitting diode layer EDL.

The encapsulation layer ENCAP can have a single layer structure or a multi-layered structure. For example, the plurality of encapsulation layers ENCAP can include a first encapsulation layer 117a, a second encapsulation layer 117b, and a third encapsulation layer 117c.

At this time, the first encapsulation layer 117a and the third encapsulation layer 117c are formed by inorganic films and the second encapsulation layer 117b is formed by an organic film. Among the first encapsulation layer 117a, the second encapsulation layer 117b, and the third encapsulation layer 117c, the second encapsulation layer 117b is thickest and can serve as a planarization layer.

The first encapsulation layer 117a is disposed on the common electrode 123 and can be disposed to be most adjacent to the light emitting diode 120. The first encapsulation layer 117a is formed of an inorganic insulating material which can be formed by low-temperature deposition. For example, the first encapsulation layer 117a can be formed by silicon nitride SiNx, silicon oxide SiOx, silicon oxynitride SiON, or aluminum oxide Al₂O₃. The first encapsulation layer 117a is deposited under a low temperature atmosphere so that during the deposition process, the damage of the emission layer 122 including an organic material which is vulnerable to the high temperature atmosphere can be suppressed.

The second encapsulation layer 117b can be formed to have a smaller area than that of the first encapsulation layer 117a. In this case, the second encapsulation layer 117b can be formed to expose both ends of the first encapsulation layer 117a. The second encapsulation layer 117b can serve as a buffer to alleviate stress between the layers due to bending of the flexible display device and to enhance planarization performance.

For example, the second encapsulation layer 117b is formed of an organic insulating material, such as acrylic resin, epoxy resin, polyimide, polyethylene, or silicon oxy carbon (SiOC). For example, the second encapsulation layer 117b can be formed by an inkjet method, but is not limited thereto.

In order to suppress the collapse of the encapsulation layer ENCAP, one or more dams can be disposed at an end portion of the inclined surface of the encapsulation layer ENCAP or in the vicinity thereof. One or more dams can be disposed in a boundary between the display area and the non-display area or in the vicinity of the boundary.

The second encapsulation layer 117b including an organic material can be located only on an inner side surface of an innermost primary dam. For example, the second encapsulation layer 117b may not be disposed on an upper portion of all the dams. In contrast, the second encapsulation layer 117b including an organic material can be disposed in the upper portion of at least the primary dam, between the primary dam and a secondary dam. For example, the second encapsulation layer 117b can be located to extend to the upper portion of the primary dam. Alternatively, the second encapsulation layer 117b can be located to extend to the upper portion of the secondary dam by passing the upper portion of the primary dam.

The third encapsulation layer 117c can be formed above the substrate SUB on which the second encapsulation layer 117b is formed so as to cover upper surfaces and side surfaces of the second encapsulation layer 117b and the first encapsulation layer 117a. At this time, the third encapsulation layer 117c can minimize or block the permeation of external moisture or oxygen into the second encapsulation layer 117b and the first encapsulation layer 117a. For example, the third encapsulation layer 117c can be formed by an inorganic insulating material, such as silicon nitride SiNx, silicon oxide SiOx, silicon oxynitride SiON, or aluminum oxide Al₂O₃.

The touch sensor layer TSL can be disposed above the above-described encapsulation layer ENCAP.

Hereinafter, a lamination structure of the touch sensor layer TSL will be described below.

A touch buffer film 118a is disposed above the encapsulation layer ENCAP and a touch sensor 140 can be disposed on the touch buffer film 118a.

The touch sensor 140 can include a touch sensor metal 141 and a bridge metal 142 located on different layers. A touch interlayer insulating film 118b can be disposed between the touch sensor metal 141 and the bridge metal 142.

For example, the touch sensor metal 141 can include a first touch sensor metal, a second touch sensor metal, and a third touch sensor metal which are disposed to be adjacent to each other. The first touch sensor metal and the second touch sensor metal are electrically connected. However, when the third touch sensor metal is disposed between the first touch sensor metal and the second touch sensor metal, the first touch sensor metal and the second touch sensor metal can be electrically connected by means of the bridge metal 142 disposed on a different layer. The bridge metal 142 can be insulated from the third touch sensor metal by a touch interlayer insulating film 118b.

When the touch sensor layer TSL is formed, chemicals (for example, developer or etchant) used for the process or moisture from the outside can be generated. The touch buffer film 118a is disposed and the touch sensor layer TSL is disposed thereon to suppress the permeation of chemicals or moisture during the manufacturing of the touch sensor layer TSL into the emission layer 122 including an organic material. By doing this, the touch buffer film 118a can suppress the damage of the emission layer 122 which is vulnerable to the chemical solution or the moisture.

The touch buffer film 118a can be formed of an organic insulating material which is formed at a temperature equal to or lower than a predetermined temperature (for example, 100° C.) to suppress the damage of the emission layer 122 including an organic material which is vulnerable to a high temperature. The organic insulating material has a low permittivity of 1 to 3. For example, the touch buffer film 118a can be formed of acrylic, epoxy, or siloxane based material. As the flexible display device is bent, the encapsulation layer ENCAP can be damaged and the touch sensor metal 141 disposed above the touch buffer film 118a can be broken. Even though the flexible display device is bent, the touch buffer film 118a which is configured of an organic insulating material to have a planarization performance can suppress the damage of the encapsulation layer ENCAP and the breakage of the metals 141 and 142 which form the touch sensor 140.

The protection layer PAC can be disposed so as to cover the touch sensor 140. The protection layer PAC can be formed by an organic insulating film.

Hereinafter, the lamination structure of the transmission area TA included in the first optical area will be described.

Referring to FIGS. 7 and 8, the substrate SUB and various insulating films 111a, 111b, 112, 113a, 113b, 114, 115a, 115b, 117a, 117b, 117c, and PAC disposed in the non-transmission area NTA of the first optical area can also be disposed in the transmission area TA of the first optical area in the same way.

However, in the non-transmission area NTA of the first optical area, a material layer (for example, a metal material layer or a semiconductor layer) having an electric characteristic or an opaque characteristic may not be disposed in the transmission area TA of the first optical area, other than the insulating material.

For example, a metal material layer 135, 131, GM, TM, 132, 133, and 125 related to the transistor and the semiconductor layer 134 are not disposed in the transmission area TA. Further, the pixel electrode 121 and the common electrode 123 included in the light emitting diode 120 may not be disposed in the transmission area TA. The emission area 122 can be disposed in the transmission area TA, or may not be disposed in the transmission area. Further, the touch sensor metal 141 and the bridge metal 142 included in the touch sensor 140 are not disposed in the transmission area TA, but the present disclosure is not limited thereto.

For example, the transmission area TA of the first optical area overlaps the first optical electronic device 150 so that for the purpose of normal operation of the first optical electronic device 150, the transmittance of the transmission area TA needs to be high.

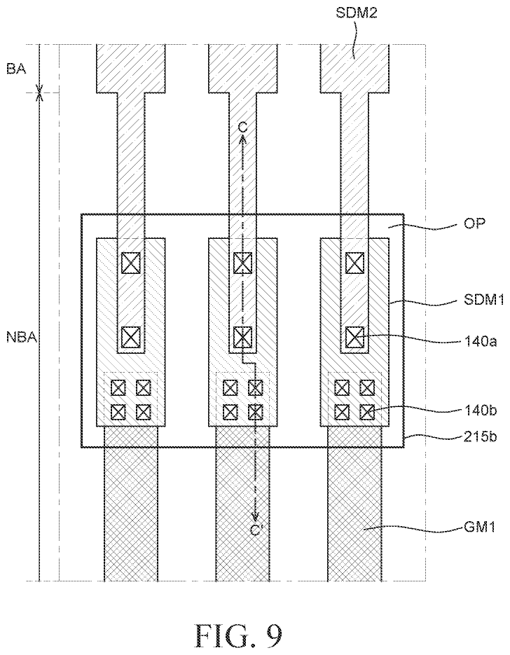

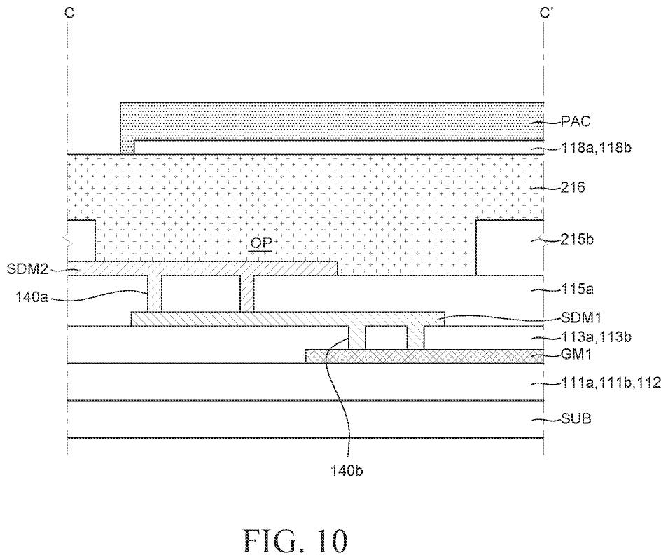

Hereinafter, a configuration of the present disclosure in which the galvanic corrosion defect of the GIP line unit is addressed or minimized will be described in detail with reference to FIGS. 9 and 10.

FIG. 9 is a plan view illustrating a GIP line unit of an exemplary embodiment of the present disclosure, and FIG. 10 is a cross-sectional view taken along the line C-C′ of FIG. 9.

Particularly, FIGS. 9 and 10 illustrate a part of the non-display area including a bending area BA and a non-bending area NBA, for example, a part of the GIP line unit.

At this time, an area other than a rectangle illustrated in FIG. 9 indicates an area in which the second planarization layer 215b is disposed.

Referring to FIGS. 9 and 10, the non-display area of the GIP line unit can include a substrate SUB, GIP lines GM1, connection lines SDM1, link lines SDM2, planarization layers 115a and 215b, a bank 216, a touch buffer film 118a, a touch interlayer insulating film 118b, and a protection layer PAC.

For the convenience of description, the substrate SUB can include a first substrate, a second substrate, and an interlayer insulating film. The interlayer insulating film can be disposed between the first substrate and the second substrate.

Various insulating films of the transistor layer, such as a multi-buffer layer 111a, an active buffer layer 111b, and a gate insulating film 112 can be disposed above the substrate SUB of the GIP line unit. However, the present disclosure is not limited thereto and some insulating film may not be disposed.

A GIP line GM1 can be disposed on the gate insulating film 112. The GIP line GM1 extends to a driving IC to be applied with a signal and extends to a pixel in the display area to transmit a signal.

The GIP line GM1 can be formed of the same metal material as the gate electrode of the transistor in the display area on the same layer as the gate electrode of the transistor in the display area, but is not limited thereto.

A first interlayer insulating film 113a and a second interlayer insulating film 113b can be disposed on the GIP line GM1.

A connection line SDM1 can be disposed on the second interlayer insulating film 113b. For example, the connection line SDM1 is disposed on the second interlayer insulating film 113b of the non-bending area NBA and can include a first contact area which is connected to the GIP line GM1.

The connection line SDM1 can connect between the link line SDM2 and the GIP line GM1. The connection line SDM1 is electrically connected to the link line SDM2, for example, a second contact area, through a plurality of first contact holes 140a and can be electrically connected to the GIP line GM1 through a plurality of second contact hole 140b.

The connection line SDM1 can be formed of the same metal material as the source electrode and the drain electrode of the transistor in the display area on the same layer as the source electrode and the drain electrode of the transistor in the display area, but is not limited thereto.

The first planarization layer 115a can be disposed on the connection line SDM1. At this time, the first planarization layer 115a can be formed of a PI based material.

The link line SDM2 can be disposed on the first planarization layer 115a. The link line SDM2 can be a wiring line which connects between the GIP line connected to the driving IC and the GIP line GM1 connected to a pixel of the display area.

The link line SDM2 is disposed on the first planarization layer 115a to extend to the bending area BA and can include a second contact area connected to the connection line SDM1.

The link line SDM2 can be formed of the same metal material as the connection electrode in the display area on the same layer as the connection electrode in the display area, but is not limited thereto.

The second planarization layer 215b can be disposed on the link line SDM2. The second planarization layer 215b can be formed of a PAC based material.

In the meantime, according to the exemplary embodiment of the present disclosure, the second planarization layer 215b above the contact area of the GIP line unit, for example, above the contact area in which the first contact hole 140a and the second contact hole 140b are disposed, is partially removed to form an open area OP. A part of the link line SDM2, for example, the second contact area, can be exposed by the open area OP.

At this time, a blocking layer can be further formed to cover an end of the link line SDM2 exposed by the open area OP, for example, a second contact area and block an end of the GIP line GM1, for example, the first contact area of the connection line SDM1.

Here, the blocking layer can be disposed in the vicinity of the first contact hole 140a through which the connection line SDM1 and the link line SDM2 are electrically connected and in the vicinity of the second contact hole 140b through which the connection line SDM1 and the GIP line GM1 are electrically connected, for example, on the link line SDM2 to block the first and second contact area.

The blocking layer can be formed of a transparent conductive material, such as ITO, IZO, and IGZO, but is not limited thereto.

The bank 216 can be disposed on the second planarization layer 215b, but is not limited thereto and in some cases, the bank 216 may not be disposed.

The bank 216 can be formed of a PI based material. The PI based material has a good adhesion with Ti of the link line SDM2 and is excellent to suppress the moisture permeation as compared with the PAC.

The bank 216 can be disposed to be filled in the open area OP of the second planarization layer 215b, but the present disclosure is not limited thereto and an insulating film which is formed of a PI based material can be used other than the bank 216.

A touch buffer film 118a and a touch interlayer insulating film 118b can be disposed on the bank 216. The protection layer PAC can be disposed on the touch interlayer insulating film 118b.

As described above, according to the exemplary embodiment of the present disclosure, the second planarization layer 215b above the contact areas of the GIP line unit is partially removed and the exposed open area OP is covered by an insulating film, such as the bank 216 or the touch buffer film 118a. Therefore, the galvanic corrosion defect of the GIP line unit is addressed or minimized and additional moisture permeation can be suppressed. The galvanic corrosion defect can be mainly caused in an area in which the potential difference between heterogeneous metals is 0.4 V or higher so that the open area OP can be formed in the entire GIP line unit or only in a partial area in which the potential difference between the heterogeneous metals is large. Further, it is free from the galvanic corrosion depending on the presence of absence of the insulating film, such as the encapsulation layer and the touch sensor layer, above the contact area so that the degree of freedom in design of the encapsulation layer and the touch sensor layer above the contact area of the GIP line unit is increased.

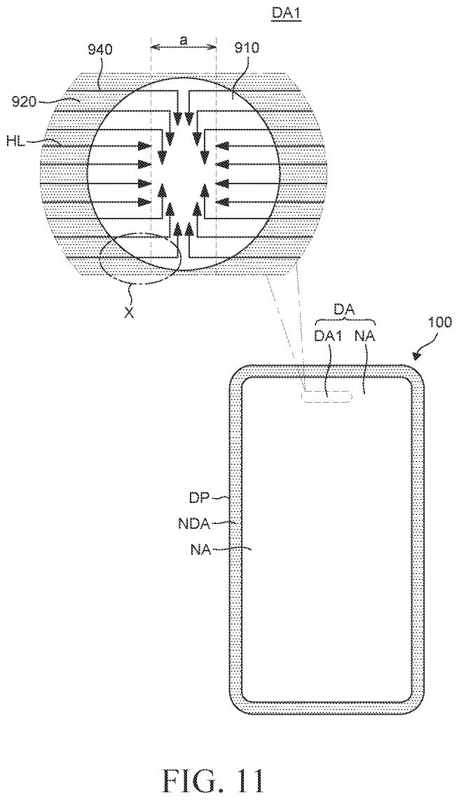

FIG. 11 is a plan view illustrating a first optical area of a flexible display device according to an exemplary embodiment of the present disclosure.

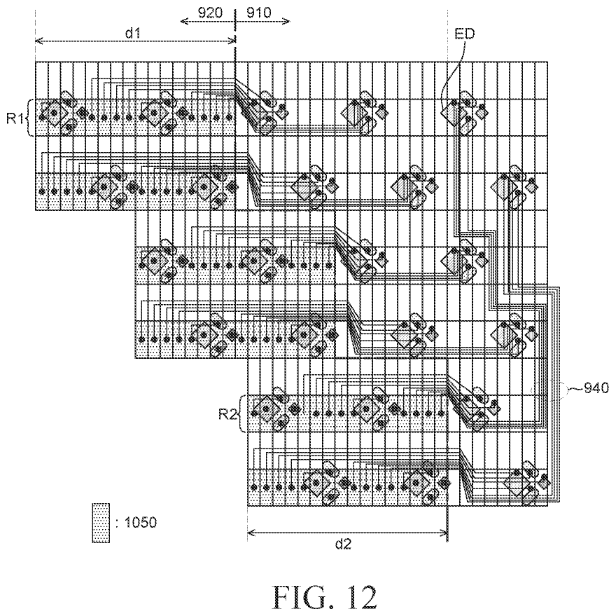

FIG. 12 is an enlarged view of an area X of FIG. 11.

First, referring to FIG. 11, the first optical area DA1 can include a center area 910 and a bezel area 920 located on the outer periphery of the center area 910.

The first optical area DA1 can include a plurality of horizontal lines HL. Transistors located in the bezel area 920 and light emitting diodes located in the center area 910 can be connected by the plurality of horizontal lines HL.

The flexible display device 100 according to the exemplary embodiment can include a routing structure 940. The routing structure 940 is included so that the center area 910 can be expanded by a predetermined area a. This is because the pixel located in the predetermined area a is connected to the transistor located in the bezel area 920 by the routing structure 940.

The structure of the first optical area DA1 including the routing structure 940 will be reviewed in detail as follows.

Referring to FIG. 12, the first optical area can include a plurality of light emitting diodes ED disposed in the center area 910 and the bezel area 920. The first optical area includes the plurality of light emitting diodes ED so that the first optical area can display a screen.

The first optical area can include a plurality of transistors 1050 located in the bezel area 920. In the center area 910, the transistor 1050 can be not located. Since the transistor 1050 is not located in the center area 910 so that the center area 910 can have a higher transmittance.

The first optical area includes a plurality of rows and can include a first row R1 and a second row R2. The plurality of rows included in the first optical area is an arbitrary area which horizontally crosses the first optical area to be defined by a pattern of the transistor 1050.

The flexible display device can include a light emitting diode ED which is located in the center area 910 and located in a first row R1 and a transistor 1050 which is located in the bezel area 920 and located in a second row R2.

The flexible display device can include a routing structure 940 which electrically connects the light emitting diode ED located in the first row R1 and the transistor 1050 located in the second row R2.

The transistor 1050 and the light emitting diode ED which are located on different rows can be connected by the routing structure 940. Therefore, a transistor 1050 located in a row in which transistors 1050 more than the light emitting diodes ED and a light emitting diode ED located in a row in which light emitting diodes ED more than transistors 1050 are disposed can be connected to each other.

The number of light emitting diodes ED included in the first row R1 in the center area 910 is much larger than the number of light emitting diodes ED included in the second row R2 in the center area 910. Accordingly, in order to drive the light emitting diode ED included in the first row R1, a more number of transistors 1050 is necessary and in order to drive the light emitting diode ED included in the second row R2, a less number of transistors 1050 is necessary. Accordingly, among the transistors 1050 located in the second row R2 of the bezel area 920, a surplus transistor 1050 which is not electrically connected to the light emitting diode ED located in the second row R2 can be electrically connected to the light emitting diode ED located in the first row R1 by the routing structure 940.

In the entire center area 910, the number of pixels for every unit area can be substantially the same. When the number of pixels for every unit area is substantially the same, for example, it can mean that one pixel pattern is substantially uniform in the entire center area 910. Accordingly, in the first row R1 having the area overlapping the center area 910 larger than the second row R2, a more number of light emitting diodes ED can be located.

For example, the number of transistors 1050 included in the first row R1 of the bezel area 920 can be substantially the same as the number of transistors 1050 included in the second row R2 of the bezel area 920. In the example, if the number of light emitting diodes ED included in the first row R1 in the center area 910 is larger and the number of light emitting diodes ED included in the second row R2 in the center area 910 is smaller, some of the transistors 1050 included in the second row R2 is not electrically connected to the light emitting diode ED located in the second row R2, but can be electrically connected to the light emitting diode ED located in the first row R1.

Further, in the entire bezel area 920, the number of transistors 1050 for every unit area is substantially the same. When the pattern of the transistor for every unit area is substantially the same, it can mean that one transistor pattern in the entire bezel area 920 is substantially uniform.

An area d1 of the bezel area 920 which overlaps the first row R1 can be substantially the same as an area d2 of the bezel area 920 which overlaps the second row R2. In such an example, the number of transistors 1050 located in the first row R1 of the bezel area 920 can be substantially the same as the number of transistors 1050 included in the second row R2 of the bezel area.

When the bezel area 920 is configured as described above, the number of transistors 1050 located in a row of the bezel area 920 is maintained to be constant and a surplus transistor in a specific row can be electrically connected to a surplus light emitting diode in the other row by the routing structure 940. Accordingly, the flexible display device according to the exemplary embodiment can have a larger center area 910 than a flexible display device of a comparative example.

The exemplary embodiments of the present disclosure can also be described as follows:

According to an aspect of the present disclosure, there is provided a flexible display device. The flexible display device includes a substrate which includes a display area divided into an optical area and a normal area and a non-display area divided into a bending area and a non-bending area. The flexible display device further includes a first insulating film disposed on the substrate. The display device further includes a wiring line disposed on the first insulating film of the non-bending area. The flexible display device further includes a second insulating film disposed on the wiring line. The flexible display device further includes a connection line which is disposed on the second insulating film of the non-bending area and has a first contact area connected to the wiring line. The flexible display device further includes a first planarization layer disposed on the connection line. The flexible display device further includes a link line which is disposed on the first planarization layer to extend to the bending area and has a second contact area connected to the connection line. The flexible display device further includes a second planarization layer which is disposed on the link line and includes an open area formed by removing a partial area to expose the second contact area of the link line. The flexible display device further includes a third insulating film which is disposed on the second planarization layer and is filled in the open area.

The first insulating film can include at least one of a multi buffer layer, an active buffer layer, and a gate insulating film. The multi buffer layer, the active buffer layer, and the gate insulating film can be different layers.

The wiring line can include a gate-in-panel (GIP) line. The GIP line can include a first part extending to a driving IC to be applied with a signal and a second part extending to a pixel in the display area to transmit a signal.

The GIP line is formed by the same metal material as a gate electrode of a transistor in the display area on the same layer as a gate electrode of a transistor in the display area.

The second insulating film can include a first interlayer insulating film and a second interlayer insulating film.

The connection line can be electrically connected to the second contact area of the link line through at least one first contact hole and be electrically connected to the wiring line through at least one second contact hole.

The connection line can be formed by the same metal material as a source electrode and a drain electrode of a transistor in the display area on the same layer as a source electrode and a drain electrode of a transistor in the display area.

The first planarization layer can be formed by a polyimide (PI) based material. The link line can connect between the first part of the GIP line connected to the driving IC and the second part of the GIP line connected to a pixel of the display area.

The link line can be formed by the same metal material as a connection electrode in the display area on the same layer as a connection electrode in the display area.

The second planarization layer can be formed by a photo-acryl (PAC) based material. The third insulating film can include a bank. The bank can be formed by a polyimide (PI) based material.

The flexible display device can further include an optical electronic device which is located below the substrate and is disposed to overlap the optical area.

The optical area can include a non-transmission area and a transmission area, the transmission area is formed by removing an opaque electrode including a cathode electrode, and the optical electronic device is located in the transmission area.

Although the exemplary embodiments of the present disclosure have been described in detail with reference to the accompanying drawings, the present disclosure is not limited thereto and can be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A flexible display device, comprising:
a substrate including a display area and a non-display area, the display area having an optical area and a main area and the non-display area having a bending area and a non-bending area;
a first insulating film disposed on the substrate;
a wiring line disposed on the first insulating film of the non-bending area;
a second insulating film disposed on the wiring line;
a connection line disposed on the second insulating film of the non-bending area and having a first contact area connected to the wiring line;
a first planarization layer disposed on the connection line;
a link line disposed on the first planarization layer to extend to the bending area and having a second contact area connected to the connection line;
a second planarization layer disposed on the link line and including an open area formed by removing a partial area to expose the second contact area of the link line; and
a third insulating film disposed on the second planarization layer and filled in the open area.

2. The flexible display device according to claim 1, wherein the first insulating film includes at least one of a multi buffer layer, an active buffer layer, and a gate insulating film,
wherein the multi buffer layer, the active buffer layer, and the gate insulating film are different layers.

3. The flexible display device according to claim 1, wherein the wiring line includes a gate-in-panel (GIP) line.

4. The flexible display device according to claim 3, wherein the GIP line includes a first part extending to a driving integrated circuit (IC) to be applied with a signal, and a second part extending to a pixel in the display area to transmit a signal.

5. The flexible display device according to claim 3, wherein the GIP line is formed by a same metal material as a gate electrode of a transistor in the display area on a same layer as a gate electrode of a transistor in the display area.

6. The flexible display device according to claim 1, wherein the second insulating film includes a first interlayer insulating film and a second interlayer insulating film.

7. The flexible display device according to claim 1, wherein the connection line is electrically connected to the second contact area of the link line through at least one first contact hole, and is electrically connected to the wiring line through at least one second contact hole.

8. The flexible display device according to claim 1, wherein the connection line is formed by a same metal material as a source electrode and a drain electrode of a transistor in the display area on a same layer as a source electrode and a drain electrode of a transistor in the display area.

9. The flexible display device according to claim 1, wherein the first planarization layer includes a polyimide (PI) based material.

10. The flexible display device according to claim 4, wherein the link line connects the first part of the GIP line connected to the driving IC to the second part of the GIP line connected to a pixel of the display area.

11. The flexible display device according to claim 1, wherein the link line is formed by a same metal material as a connection electrode in the display area on a same layer as a connection electrode in the display area.

12. The flexible display device according to claim 1, wherein the second planarization layer includes a photo-acryl (PAC) based material.

13. The flexible display device according to claim 1, wherein the third insulating film includes a bank.

14. The flexible display device according to claim 13, wherein the bank includes polyimide (PI) based material.

15. The flexible display device according to claim 1, further comprising:
an optical electronic device disposed below the substrate to overlap the optical area.

16. The flexible display device according to claim 15, wherein the optical area includes a non-transmission area and a transmission area,
the transmission area is formed by removing an opaque electrode including a cathode electrode, and
the optical electronic device is located in the transmission area.

17. The flexible display device according to claim 15, wherein a horizontal line which passes through the optical area avoids the transmission area in the optical area.

18. The flexible display device according to claim 17, wherein the horizontal line which passes through the optical area includes a curved section or a bending section which detours outside of an outer edge of the transmission area.

19. The flexible display device according to claim 15, wherein a vertical line which passes through the optical area avoids the transmission area in the optical area.

20. The flexible display device according to claim 19, wherein the vertical line which passes through the optical area includes a curved section or a bending section which detours outside of an outer edge of the transmission area.

21. The flexible display device according to claim 15, wherein the optical area includes a center area and a bezel area located on an outer periphery of the center area,
the optical area further includes a plurality of light emitting diodes disposed in the center area and the bezel area and a plurality of transistors located in the bezel area,
the number of transistors included in a first row of the bezel area is substantially the same as the number of transistors included in a second row of the bezel area,
the number of light emitting diodes included in a first row in the center area is different from the number of light emitting diodes included in a second row in the center area, and
a surplus transistor in one row is electrically connected to a surplus light emitting diode in another row by a routing structure.
